(19) United States
(12) Patent Application Publication
(10) Pub. No.: US 2026/0230087 A1
(43) Pub. Date: Aug. 6, 2026

(54) SYSTEMS AND METHODS OF HYBRID RESISTIVE DIGITAL-TO-ANALOG CONVERTERS

(71) Applicant: Samsung Electronics Co., Ltd., Suwon-si (KR)

(72) Inventors: Hyunwook KANG, San Diego, CA (US); Joon-Young PARK, San Diego, CA (US)

(21) Appl. No.: 19/172,636

(22) Filed: Apr. 7, 2025

Related U.S. Application Data
(60) Provisional application No. 63/753,913, filed on Feb. 4, 2025.

(51) Int. Cl. H03M 1/68; H03M 1/66; H03M 1/78

(52) U.S. Cl. CPC H03M 1/682; H03M 1/662; H03M 1/785

(57) ABSTRACT

Provided are systems, methods, and apparatuses for hybrid resistive digital-to-analog converters (DACs). In one or more examples, the systems, devices, and methods include connecting a set of resistors of a first DAC of a circuit in series, the set of resistors connected to a multiplexor, an output of the circuit providing the reference voltage; connecting a set of R-2 R resistors of a second DAC of the circuit, the set of R-2 R resistors comprising a first resistor with a value R and a second resistor with a value 2 R, the value R being half the value 2 R; and connecting a scaling circuit between the first DAC and the second DAC, the scaling circuit being configured to modify a resolution of the second DAC relative to a resolution of the first DAC.

### CROSS-REFERENCE TO RELATED APPLICATIONS

This application claims the benefit of U.S. Provisional Patent Application Ser. No. 63/753,913 filed Feb. 4, 2025, which is incorporated by reference herein for all purposes.

### TECHNICAL FIELD

The disclosure relates generally to integrated circuits. In particular, the subject matter relates to hybrid resistive digital-to-analog converters (DACs).

### BACKGROUND

Digital to analog converters (DACs) can include integrated circuits that convert digital signals (e.g., logical 1s and logical 0s) into analog signals (e.g., continuous waveforms). DACs can be used to bridge the digital world of computers with the analog world of sound, images, and other physical phenomena. DACs can be used in any device that uses digital and analog signals or any device that converts digital signals to analog signals, including computers, smartphones, tablets, CD players, Blu-ray players, TVs, etc.

### SUMMARY

In various embodiments, the systems and methods described herein include systems, methods, and apparatuses for hybrid resistive digital-to-analog converters (DACs). In some aspects, the techniques described herein relate to a circuit including: a first digital-to-analog converter (DAC) including a set of resistors connected in series, the set of resistors connected to a multiplexor, a first resistor of the set of resistors connected to a positive reference voltage of the circuit and a second resistor of the set of resistors connected to a negative reference voltage of the circuit, an output of the circuit providing a reference voltage; a second DAC including a set of R-2 R resistors, the set of R-2 R resistors including a first resistor with a value R and a second resistor with a value 2 R, the value R being half the value 2 R; and a scaling circuit to modify a resolution of the second DAC relative to a resolution of the first DAC, the scaling circuit connecting the first DAC to the second DAC.

In some aspects, the techniques described herein relate to a circuit, wherein the scaling circuit is connected to an output of the multiplexor, an output of the second DAC, and the output of the circuit.

In some aspects, the techniques described herein relate to a circuit, wherein the scaling circuit includes a scaling resistor, a value of the scaling resistor being based on a quotient determined from the value 2 R and a number of bits associated with the first DAC.

In some aspects, the techniques described herein relate to a circuit, wherein the scaling circuit includes a scaling resistor with the value 2 R and at least one R-2 R pair of scaling resistors connected to the output of the second DAC.

In some aspects, the techniques described herein relate to a circuit, wherein the set of resistors of the first DAC are of a same type of resistor and of a same value of resistor.

In some aspects, the techniques described herein relate to a circuit, wherein a value of a resistor of the set of resistors of the first DAC is set to the value R from the second DAC.

In some aspects, the techniques described herein relate to a circuit, wherein a value of a resistor of the set of resistors of the first DAC is different from the value R from the second DAC.

In some aspects, the techniques described herein relate to a circuit, wherein: an input of the circuit includes a binary code, the first DAC is associated with M coarse bits of the binary code, the M coarse bits including a most significant bit of the binary code, and the second DAC is associated with N fine bits of the binary code, the N fine bits including a least significant bit of the binary code, M and N being positive integers, M being greater than, less than, or equal to N.

In some aspects, the techniques described herein relate to a circuit, wherein the second resistor of the set of R-2 R resistors is connected to a reference switch that switches between the positive reference voltage and the negative reference voltage.

In some aspects, the techniques described herein relate to a circuit including: a first digital-to-analog converter (DAC) including a set of resistors connected in series, a first resistor of the set of resistors connected to a multiplexor and a second resistor of the set of resistors connected to the multiplexor; a second DAC including a first set of R-2 R resistors, the first set of R-2 R resistors including a first R resistor with a value R and a first 2 R resistor with a value 2 R, the first resistor of the set of resistors being connected to an output of the second DAC; a third DAC including a second set of R-2 R resistors, the second set of R-2 R resistors including a second R resistor with the value R and a second 2 R resistor with the value 2 R, the value R being half the value 2 R, the second resistor of the set of resistors being connected to an output of the third DAC; a termination resistor of the second DAC connected to a positive reference voltage of the circuit; and a termination resistor of the third DAC connected to a negative reference voltage of the circuit, an output of the circuit providing a reference voltage.

In some aspects, the techniques described herein relate to a circuit, wherein: the first DAC receives an output of the second DAC and an output of the third DAC, and an output of the multiplexor provides the output of the circuit.

In some aspects, the techniques described herein relate to a circuit, wherein the set of resistors of the first DAC are of a same type of resistor and of a same value of resistor.

In some aspects, the techniques described herein relate to a circuit, wherein a value of a resistor of the set of resistors of the first DAC is set to the value R from the second DAC or the third DAC.

In some aspects, the techniques described herein relate to a circuit, wherein a value of a resistor of the set of resistors of the first DAC is different from the value R from the second DAC or the third DAC.

In some aspects, the techniques described herein relate to a circuit, wherein: an input of the circuit includes a binary code, the first DAC is associated with M coarse bits of the binary code, the M coarse bits including a most significant bit of the binary code, and the second DAC and the third DAC are associated with N fine bits of the binary code, the N fine bits including a least significant bit of the binary code, M and N being positive integers, M being greater than, less than, or equal to N.

In some aspects, the techniques described herein relate to a circuit, wherein the first 2 R resistor of the second DAC is connected to a reference switch that switches between the positive reference voltage and the negative reference voltage.

In some aspects, the techniques described herein relate to a method of providing a reference voltage, the method including: connecting a set of resistors of a first digital-to-analog converter (DAC) of a circuit in series, the set of resistors connected to a multiplexor, a first resistor of the set of resistors connected to a positive reference voltage of the circuit and a second resistor of the set of resistors connected to a negative reference voltage of the circuit, an output of the circuit providing the reference voltage; connecting a set of R-2 R resistors of a second DAC of the circuit, the set of R-2 R resistors including a first resistor with a value R and a second resistor with a value 2 R, the value R being half the value 2 R; and connecting a scaling circuit between the first DAC and the second DAC, the scaling circuit being configured to modify a resolution of the second DAC relative to a resolution of the first DAC.

In some aspects, the techniques described herein relate to a method, wherein the scaling circuit is connected to an output of the multiplexor, an output of the second DAC, and the output of the circuit.

In some aspects, the techniques described herein relate to a method, wherein the scaling circuit includes a scaling resistor, a value of the scaling resistor being based on a quotient determined from the value 2 R and a number of bits associated with the first DAC.

In some aspects, the techniques described herein relate to a method, wherein the scaling circuit includes a scaling resistor with the value 2 R and at least one R-2 R pair of scaling resistors connected to the output of the second DAC.

In some aspects, the techniques described herein relate to a device including: a digital-to-analog converter (DAC) circuit configured to output a reference voltage for an operation of the device, the DAC circuit including: a first DAC including a set of resistors connected in series, the set of resistors connected to a multiplexor, a first resistor of the set of resistors connected to a positive reference voltage of the circuit and a second resistor of the set of resistors connected to a negative reference voltage of the circuit; a second DAC including a set of R-2 R resistors, the set of R-2 R resistors including a first resistor with a value R and a second resistor with a value 2 R, the value R being half the value 2 R; and a scaling circuit to modify a resolution of the second DAC relative to a resolution of the first DAC, the scaling circuit connecting the first DAC to the second DAC.

In some aspects, the techniques described herein relate to a device, wherein the scaling circuit is connected to an output of the multiplexor, an output of the second DAC, and the output of the circuit.

In some aspects, the techniques described herein relate to a device, wherein the scaling circuit includes a scaling resistor, a value of the scaling resistor being based on the value 2 R.

In some aspects, the techniques described herein relate to a device, wherein the device includes a memory device, the device being configured to determine whether a memory cell of the device stores a logical 1 or a logical 0 based on the reference voltage.

The systems and methods of hybrid resistive digital-to-analog converters (R-DACs) and R-2 R DACs described herein include multiple advantages and benefits. For example, the hybrid R and R-2 R DACs described herein reduce the number of components, logic gates, etc., associated with DACs, resulting in reduced systems costs. Also, the hybrid R and R-2 R DACs described herein provide flexibility in adjusting the cost per area depending on the target linearity constraints. In addition, the hybrid R and R-2 R DACs described herein provide a relatively high linearity performance based on configuring the R-DAC to handle coarse bits, where the impact on overall linearity can be an important factor in system performance. Also, the hybrid R and R-2 R DACs described herein simplify the decoder and MUX switch design overhead by reducing the number of resistors and decoder logics associated with the fine bits of a DAC input.

### BRIEF DESCRIPTION OF THE DRAWINGS

The above-mentioned aspects and other aspects of the present systems and methods will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

These and other features and advantages of the present disclosure will be appreciated and understood with reference to the specification, claims, and appended drawings, wherein:

FIG. 1 illustrates an example system in accordance with one or more implementations as described herein.

FIG. 2 illustrates an example circuit in accordance with one or more implementations as described herein.

FIG. 3 illustrates an example circuit in accordance with one or more implementations as described herein.

FIG. 4 illustrates an example circuit in accordance with one or more implementations as described herein

While the present systems and methods are susceptible to various modifications and alternative forms, specific embodiments thereof are shown by way of example in the drawings and will herein be described. The drawings may not be to scale. It should be understood, however, that the drawings and detailed description thereto are not intended to limit the present systems and methods to the particular form disclosed, but to the contrary, the intention is to cover all modifications, equivalents, and alternatives falling within the spirit and scope of the present systems and methods as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

Various embodiments of the present disclosure now will be described more fully hereinafter with reference to the accompanying drawings, in which some, but not all embodiments are shown. Indeed, the disclosure may be embodied in many forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Like numbers refer to like elements throughout. Arrows in each of the figures depict bi-directional data flow and/or bi-directional data flow capabilities. The terms “path,” “pathway” and “route” are used interchangeably herein.

Embodiments of the present disclosure may be implemented in various ways, including as computer program products that comprise articles of manufacture. A computer program product may include a non-transitory computer-readable storage medium storing applications, programs, program components, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media includes all computer-readable media (including volatile and non-volatile media).

In one embodiment, a non-volatile computer-readable storage medium may include a floppy disk, flexible disk, hard disk, solid-state storage (SSS) (for example a solid-state drive (SSD)), solid state card (SSC), solid state module (SSM), enterprise flash drive, magnetic tape, or any other non-transitory magnetic medium, and/or the like. A non-volatile computer-readable storage medium may include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may include read-only memory (ROM), programmable read-only memory (PROM), erasable programmable read-only memory (EPROM), electrically erasable programmable read-only memory (EEPROM), flash memory (for example Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may include conductive-bridging random-access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory component (RIMM), dual in-line memory component (DIMM), single in-line memory component (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of a hardware embodiment, a computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, a hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially, such that one instruction is retrieved, loaded, and executed at a time. In some example embodiments, retrieval, loading, and/or execution may be performed in parallel, such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms, and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms, and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on chip (SoC), an assembly, and so forth

The provided description is presented to enable one of ordinary skill in the art to make and use the subject matter disclosed herein and to incorporate it in the context of particular applications. While the following is directed to specific examples, other and further examples may be devised without departing from the basic scope thereof.

Various modifications, as well as a variety of uses in different applications, will be readily apparent to those skilled in the art, and the general principles defined herein may be applied to a wide range of embodiments. Thus, the subject matter disclosed herein is not intended to be limited to the embodiments presented, but is to be accorded the widest scope consistent with the principles and novel features disclosed herein.

In the description provided, numerous specific details are set forth in order to provide a more thorough understanding of the subject matter disclosed herein. It will, however, be apparent to one skilled in the art that the subject matter disclosed herein may be practiced without necessarily being limited to these specific details. In other instances, well-known structures and devices are shown in block diagram form, rather than in detail, in order to avoid obscuring the subject matter disclosed herein.

All the features disclosed in this specification (e.g., any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described herein with reference to the figures. It should be noted that the figures are only intended to facilitate the description of the features. The various features described are not intended as an exhaustive description of the subject matter disclosed herein or as a limitation on the scope of the subject matter disclosed herein. Additionally, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

It is noted that, if used, the labels left, right, front, back, top, bottom, forward, reverse, clockwise and counterclockwise have been used for convenience purposes only and are not intended to imply any particular fixed direction. Instead, the labels are used to reflect relative locations and/or directions between various portions of an object.

Data processing may include data buffering, aligning incoming data from multiple communication lanes, forward error correction (FEC), etc. For example, data may be received by an analog front end (AFE), which can prepare the incoming data for digital processing. The digital portion of the transceivers (e.g., digital signal processor (DSP)) may provide skew management, equalization, reflection cancellation, and/or other functions. It is to be appreciated that the process described herein can provide many benefits, including saving both power and cost.

Moreover, the terms “system,” “component,” “module,” “interface,” “model,” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Unless explicitly stated otherwise, each numerical value and range may be interpreted as being approximate, as if the word “about” or “approximately” preceded the value of the value or range. Signals and corresponding nodes or ports might be referred to by the same name and are interchangeable for purposes here.

While embodiments may have been described with respect to circuit functions, the embodiments of the subject matter disclosed herein are not limited. Possible implementations may be embodied in a single integrated circuit, a multi-chip module, a single card, SoC, or a multi-card circuit pack. As would be apparent to one skilled in the art, the various embodiments might also be implemented as part of a larger system. Such embodiments may be employed in conjunction with, for example, a digital signal processor, microcontroller, field-programmable gate array, application-specific integrated circuit, or general-purpose computer.

The systems and methods described herein may be based on and/or may include digital-to-analog converters (DACs). DACs can include integrated circuits that convert digital signals (e.g., logical 1s, logical 0s) into analog signals (e.g., continuous waveforms). Some systems may include resistive DACs (R-DACs). Some R-DACs can be based on a string of resistors in series, but R-DACs can include a relatively large number of resistors, which can result in a relatively complex decoder design. Some systems may include resistor ladder DACs (e.g., R-2 R DACs). Some R-2 R DACs can include relatively small number of resistors, but can perform poorly on linearity (e.g., exceed linearity constraints). Some systems can include hybrid capacitive (C) DACs and R-2 R DACs, which can include a relatively compact design with a relatively high degree of linearity in the output, but the performance of hybrid C and R-2 R DACs can decrease based on current leakage. For example, current can leak through switches connected to the capacitors, draining the charges in the capacitors, which can cause the output voltage to drift over time.

With some systems, the number of resistors can increase as the number of bits increase. For example, 4 resistors may be used for a 2-bit system, but 1,024 resistors may be used for a 10-bit system. As the density of memory increases, the greater the number of resistors that may be used in a given R-DAC. The more resistors, the larger the circuit area, which increases costs and power consumption. For example, the complexity of the MUX (e.g., decoder and switch circuitry) can grow exponentially as the number of resistors increases, which can result in exponential increases in cost and power.

The systems and methods described herein may include and/or may be based on a hybrid DAC based on an R-DAC and R-2 R DAC. R-2 R can refer to a resistor ladder network that includes resistors with values R and 2 R, where R is half or around half the value of 2 R. Using the R and 2 R values, a ladder may be constructed of resistors (e.g., as discrete components, within a silicon chip, etc.). The R-2 R ladder results in a voltage output of a fraction of a reference voltage depending on the bit value of a digital input. In some cases, the hybrid DAC may be implemented to provide a reference voltage for use in controlling a range of circuits (e.g., reference voltage for determining logical 1 or logical 0 stored in a DRAM cell, determine bias voltage for current controls, etc.).

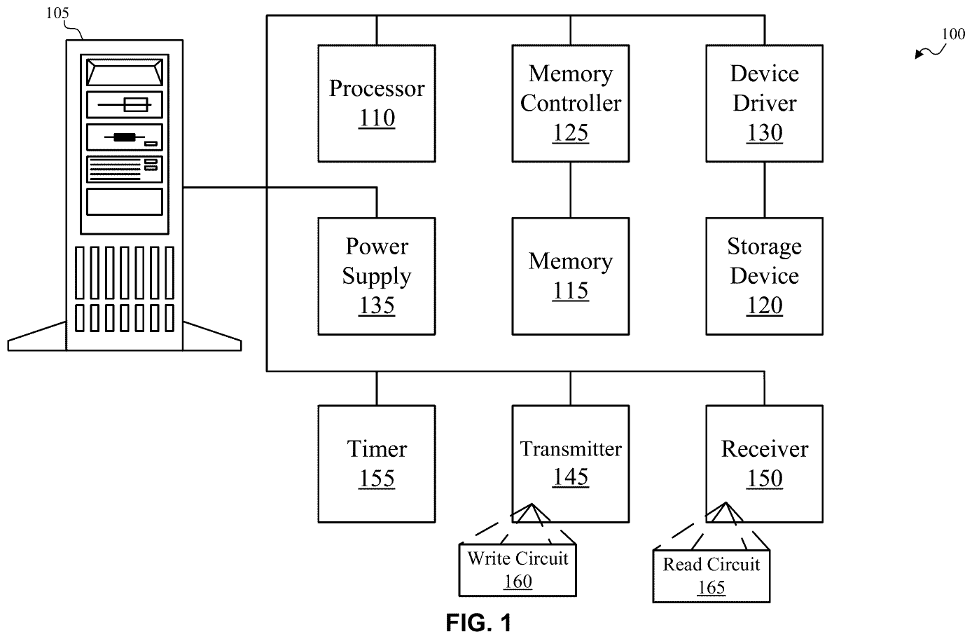

FIG. 1 illustrates an example system 100 in accordance with one or more implementations as described herein. In FIG. 1, machine 105, which may be termed a host, a system, or a server, is shown. While FIG. 1 depicts machine 105 as a tower computer, embodiments of the disclosure may extend to any form factor or type of machine. For example, machine 105 may be a rack server, a blade server, a desktop computer, a tower computer, a mini tower computer, a desktop server, a laptop computer, a notebook computer, a tablet computer, etc.

Machine 105 may include processor 110, memory 115, and storage device 120. Processor 110 may be any variety of processor. It is noted that processor 110, along with the other components discussed below, are shown outside the machine for ease of illustration: embodiments of the disclosure may include these components within the machine. While FIG. 1 shows a single processor 110, machine 105 may include any number of processors, each of which may be single core or multi-core processors, each of which may implement a Reduced Instruction Set Computer (RISC) architecture or a Complex Instruction Set Computer (CISC) architecture (among other possibilities), and may be mixed in any desired combination.

Processor 110 may be coupled to memory 115. Memory 115 may be any variety of memory, such as flash memory, DRAM, SRAM, Persistent Random Access Memory, Ferroelectric Random Access Memory (FRAM), or Non-Volatile Random Access Memory (NVRAM), such as Magnetoresistive Random Access Memory (MRAM), Phase Change Memory (PCM), or Resistive Random-Access Memory (ReRAM). Memory 115 may include volatile and/or non-volatile memory. Memory 115 may use any desired form factor: for example, Single In-Line Memory Module (SIMM), Dual In-Line Memory Module (DIMM), Non-Volatile DIMM (NVDIMM), etc. Memory 115 may be any desired combination of different memory types, and may be managed by memory controller 125. Memory 115 may be used to store data that may be termed short-term; that is, data not expected to be stored for extended periods of time. Examples of short-term data may include temporary files, data being used locally by applications (which may have been copied from other storage locations), and the like.

Processor 110 and memory 115 may support an operating system under which various applications may be running. These applications may issue requests (which may be termed commands) to read data from or write data to either memory 115 or storage device 120. When storage device 120 is used to support applications reading or writing data via some sort of file system, storage device 120 may be accessed using device driver 130. While FIG. 1 shows one storage device 120, there may be any number (one or more) of storage devices in machine 105. Storage device 120 may support any desired protocol or protocols, including, for example, the Non-Volatile Memory Express (NVMe®) protocol, a Serial Attached Small Computer System Interface (SCSI) (SAS) protocol, or a Serial AT Attachment (SATA) protocol. Storage device 120 may include any desired interface, including, for example, a Peripheral Component Interconnect Express (PCIe®) interface, or a Compute Express Link (CXL®) interface. Storage device 120 may take any desired form factor, including, for example, a U.2 form factor, a U.3 form factor, a M.2 form factor, Enterprise and Data Center Standard Form Factor (EDSFF) (including all of its varieties, such as E1 short, E1 long, and the E3 varieties), or an Add-In Card (AIC).

While FIG. 1 uses the term “storage device,” embodiments of the disclosure may include any storage device formats that may benefit from the use of computational storage units, examples of which may include hard disk drives, Solid State Drives (SSDs), or persistent memory devices, such as PCM, ReRAM, or MRAM. Any reference to “storage device” “SSD” below should be understood to include such other embodiments of the disclosure and other varieties of storage devices. In some cases, the term “storage unit” may encompass storage device 120 and memory 115.

Machine 105 may include power supply 135. Power supply 135 may provide power to machine 105 and its components. Machine 105 may include transmitter 145 and receiver 150. Transmitter 145 or receiver 150 may be respectively used to transmit or receive data. In some cases, transmitter 145 and/or receiver 150 may be used to communicate with memory 115 and/or storage device 120. Transmitter 145 may include write circuit 160, which may be used to write data into storage, such as a register, in memory 115 and/or storage device 120. In a similar manner, receiver 150 may include read circuit 165, which may be used to read data from storage, such as a register, from memory 115 and/or storage device 120. In the illustrated example, machine 105 may include timer 155, which may be used to time one or more operations, indicate or measure a time period, indicate a lapse of time, indicate an expiration, indicate a timeout, etc.

In one or more examples, machine 105 may be implemented with any type of apparatus. Machine 105 may be configured as (e.g., as a host of) one or more servers, such as a compute server, a storage server, storage node, a network server, a supercomputer, data center system, and/or the like, or any combination thereof. Additionally, or alternatively, machine 105 may be configured as (e.g., as a host of) one or more computers, such as a workstation, a personal computer, a tablet, a smartphone, and/or the like, or any combination thereof. Machine 105 may be implemented with any type of apparatus that may be configured as a device including, for example, an accelerator device, a storage device, a network device, a memory expansion and/or buffer device, a central processing unit (CPU), a graphics processing unit (GPU), a neural processing unit (NPU), a tensor processing unit (TPU), optical processing units (OPU), and/or the like, or any combination thereof.

Any communication between devices including machine 105 (e.g., host, computational storage device, and/or any intermediary device) can occur over an interface that may be implemented with any type of wired and/or wireless communication medium, interface, protocol, and/or the like including PCIe, NVMe, Ethernet, NVMe-oF, Compute Express Link (CXL), and/or a coherent protocol such as CXL.mem, CXL.cache, CXL.IO and/or the like, Gen-Z, Open Coherent Accelerator Processor Interface (OpenCAPI), Cache Coherent Interconnect for Accelerators (CCIX), Advanced eXtensible Interface (AXI) and/or the like, or any combination thereof, Transmission Control Protocol/Internet Protocol (TCP/IP), FibreChannel, InfiniBand, Serial AT Attachment (SATA), Small Computer Systems Interface (SCSI), Serial Attached SCSI (SAS), iWARP, any generation of wireless network including 2G, 3G, 4G, 5G, and/or the like, any generation of Wi-Fi, Bluetooth, near-field communication (NFC), and/or the like, or any combination thereof. In some embodiments, the communication interfaces may include a communication fabric including one or more links, buses, switches, hubs, nodes, routers, translators, repeaters, and/or the like. In some embodiments, system 100 may include one or more additional apparatus having one or more additional communication interfaces. The systems and methods described herein may be based on system 100. For example, system 100 may implement a circuit based on the systems and methods described herein. In some cases, system 100 may implement a hybrid digital-to-analog converter (DAC) circuit. The hybrid DAC circuit may include or may be based on at least one resistive DAC (R-DAC) and at least one R-2 R DAC. At least one component of system 100 may include or implement the hybrid DAC circuit.

In some examples, processor 110, memory 115, storage device 120, memory controller 125, and/or device driver 130 may include or operate in conjunction with the hybrid DAC circuit described herein. For example, the hybrid DAC circuit may provide a voltage reference to at least one of processor 110, memory 115, storage device 120, memory controller 125, and/or device driver 130. In some examples, transmitter 145 and/or receiver 150 may include or operate in conjunction with the hybrid DAC circuit described herein. For example, the hybrid DAC circuit may provide a voltage reference to at least one of transmitter 145 and/or receiver 150.

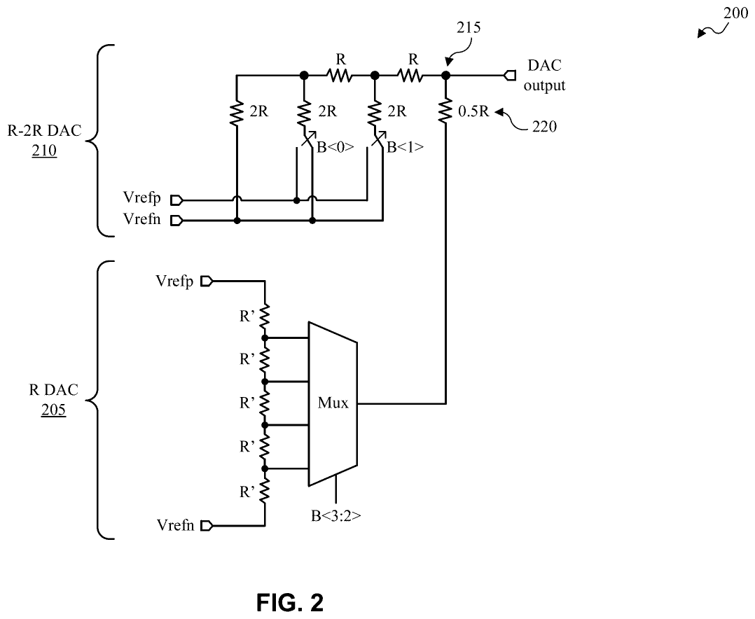

FIG. 2 illustrates an example circuit 200 in accordance with one or more implementations as described herein. In some configurations, one or more aspects of circuit 200 may be implemented by or in conjunction with system 100 of FIG. 1 or at least one component of system 100. In some configurations, one or more aspects of circuit 200 may be implemented by or in conjunction with machine 105, components of machine 105, or any combination thereof.

As shown, circuit 200 may include a first DAC (e.g., R DAC 205) and a second DAC (e.g., R-2 R DAC 210). As shown, R DAC 205 may connect to R-2 R DAC 210 via a scaling resistor (e.g., scaling resistor 220). In some cases, circuit 200 may provide a reference voltage for use in controlling one or more aspects of a device (e.g. reference voltage for determining logical 1 or logical 0 in DRAM memory, reference voltage for determining bias voltage for current controls, etc.).

In some cases, a digital analog converter (DAC) may be configured to receive a control value (e.g., binary code, digital code) and provide an output based on said control value (e.g., depicted DAC output, an overall DAC output, etc.). For example, a DAC may output an analog voltage level based on the received control value. In a 4-bit system where Vrefp is 1 volt and Vrefn is 0 volts, a DAC may output a value at or near 0 volts for a control value of 0000 and output a value at or near 1 volt for a control value of 1111. The same configuration may output values between 0 volts and 1 volt for binary values between 0000 and 1111.

DACs can be designed with attention to both coarse and fine bits to achieve a relatively high overall resolution, while simplifying internal circuitry. Coarse bits can handle larger voltage swings, while fine bits can provide finer adjustments for small changes in output voltage. The ratio between the coarse and fine bits can be referred to as the gain ratio or weighting ratio. This ratio can determine how much each coarse bit or each fine bit contributes to the overall output.

In some cases, an R-2 R DAC may be configured to convert fine bits (e.g., least significant bits) of the control value and an R DAC may be configured to convert the coarse bits (e.g., most significant bits). Thus, coarse bits may represent relatively large voltage changes, while fine bits may represent relatively small, precise adjustments. In some examples, an R-2 R DAC may convert bits B<0> and B<1> of the control value and an R DAC may convert bits B<2> and B<3>. Alternatively, an R-2 R DAC may be configured to convert the coarse bits of the control value and an R DAC may be configured to convert the fine bits. In some examples, the configuration of reference voltages routed to an R-2 R DAC (e.g., Vrefp, Vrefn) may be configured based on at least one of output common voltage, desired control range, etc. The output voltage range of an R DAC and/or an R-2 R DAC may range from Vrefp to Vrefn.

A shown, R DAC 205 may include a string of resistors in series. One of these resistors may be connected to a positive voltage reference (e.g., Vrefp, 5 volts, 3 volts, 1 volt, etc.) and another of the resistors may be connected to a negative voltage reference (e.g., Vrefn, ground, etc.). In the illustrated example, R DAC 205 may include a multiplexor (MUX) that connects to nodes between resistors in the string of resistors. In the illustrated example, an input of the MUX of R DAC 205 may connect to four nodes between five resistors. In some cases, the MUX of R DAC 205 may decode the input of the MUX (e.g., voltage levels). In some cases, the MUX of R DAC 205 may include logic gates (e.g., one or more inverters connected to one or more AND gates). The number of resistors R′ in the series of resistors and the number of MUX connections may vary between different implementations.

In the illustrated example, R-2 R DAC 210 may include a ladder network of 2 R resistors and R resistors. The left-most 2 R resistor (e.g., termination 2 R resistor) may connect to Vrefn (e.g., ground). The termination 2 R resistor may connect to ground to provide a path for current flowing through the ladder network to return to ground.

As shown, the R-2 R ladder network of R-2 R DAC 210 may use resistors of value R and 2 R to create a binary-weighted voltage divider. A first R and 2 R pair of resistors may control a first bit (e.g., B<0>, least significant bit) based on a first reference switch that connects the first R and 2 R pair of resistors to Vrefp (e.g., indicating logical 1 for B<0>) or Vrefn (e.g., indicating logical 0 for B<0>). A second R and 2 R pair of resistors may control a second bit (e.g., B<1>) based on a second reference switch that connects the first R and 2 R pair of resistors to Vrefp (e.g., indicating logical 1 for B<1>) or Vrefn (e.g., indicating logical 0 for B<1>). Accordingly, the depicted reference switches may be configured to provide an output voltage level that corresponds to a control code received by circuit 200. In various examples, the number of R and 2 R pairs may vary depending on the number of coarse/fine bits desired.

The resistor types implemented in circuit 200 may include at least one of integrated resistors (e.g. bulk/diffusion, thin-film, epitaxial resistors), carbon composition resistors, carbon film resistors, metal film resistors, metal glaze resistors, wire-wound resistors, metal oxide film resistors, foil resistors, etc. Using fewer resistors can lead to lower costs due to reduced inventory and simpler manufacturing processes, as well as reduced silicon area that removed resistors would have otherwise occupied. As shown, R DAC 205 may include resistors with value R′ and R-2 R DAC 210 may include resistors with value R and 2 R (e.g., value of R is half or about half the value of 2 R). In some cases, R′ may be equal to R. Alternatively, R′ may be equal to 2 R or some other resistor value different from R and 2 R. In some cases, the R′ are all the same value and same type of resistor. The R resistors of R-2 R DAC 210 may be of the same value and same type of resistor. The 2 R resistors of R-2 R DAC 210 may be of the same value and same type of resistor. In some cases, the R resistors of R-2 R DAC 210 may be of the same or different type of resistor as 2 R resistors of R-2 R DAC 210. The R resistors of R-2 R DAC 210 may be of the same or different type of resistor as R′ resistors of R DAC 205. The 2 R resistors of R-2 R DAC 210 may be of the same or different type of resistor as R′ resistors of R DAC 205.

As shown, an output of the MUX may connect to scaling resistor 220. Scaling resistor 220 may scale a resolution of R-2 R DAC 210 relative to a resolution of R DAC 205. In the context of a DAC, resolution can refer to the smallest increment or step size in the output voltage that the DAC can produce (e.g., smallest step size in the output voltage of circuit 200). Thus, the resolution of circuit 200 may be based on the voltage output from just the least significant bit (e.g., B<0>).

In some examples, scaling resistor 220 may bridge R DAC 205 to R-2 R DAC 210. The value of scaling resistor 220 may be based on a desired coarse-to-fine ratio, redundancy, impedance mismatch, etc. In the depicted example, scaling resistor 220 may have a value of 0.5R (e.g., half or around half the value of R, a quarter or around a quarter of the value of 2 R). Based on scaling resistor 220, a bit resolution of R-2 R DAC 210 may be reduced by a factor of 4 relative to a resolution of R DAC 205. Thus, scaling resistor 220 may provide a 4:1 coarse-to-fine ratio for circuit 200, based on the scaling resistor 220 being reduced by a factor of 4 (e.g., 0.5R=2 R/4), providing a 4-fold ratio reduction in the fine bits. The value of scaling resistor 220 may be selected based on the number of bits converted by R DAC 205 and the R-2 R DAC 210. For example, the value of scaling resistor 220 may be based on the value of a 2 R resistor of R-2 R DAC 210 divided by the number of bits N converted by R DAC 205. In the depicted example, R DAC 205 may convert 2 bits (e.g., N=2). Accordingly, the value of scaling resistor 220 may be based on the quotient of 2 R/(2\hat{ }N)=2 R/4=0.5R. If R DAC 205 is configured to convert 3 bits (e.g., N=3), then the value of scaling resistor 220 may be based on the quotient of 2 R/(2\hat{ }N)=2 R/8=0.25R.

The depicted resistive ladder of circuit 200 provides (e.g., constantly provides) a consistent current that defines the reference voltage in between resistors. The leakage current through any MUX or reference switches is negligible in comparison to the consistent current through the resistors. For example, based on the depicted configuration of circuit 200, the reference voltage may be in a constant refresh state with a consistent or stable current provided through the resistors that define reference voltages.

By employing the hybrid R and R-2 R DAC described herein (e.g., circuit 200), the number of resistors in the resistive ladder is reduced by 4-fold based on 2 fine bits in R-2 R DAC 210. Also, the number of MUX switches as well as that of MUX controlling logic gates are reduced by a factor of 4. This factor of reduction (e.g., 4-fold etc.) can depend on what resolution is selected for the coarse R-DAC. When a 1-bit R-DAC is used with a 3-bit R-2 R DAC, two Rs with a 2:1 MUX may be implemented, relieving the area and power overhead in designing the R-DAC. Furthermore, when the resolution is increased with one additional fine-bit, the overhead in doing so is another R-2 R pair and a corresponding reference switch, providing greater design flexibility in adjusting between the linearity performance and the cost overhead. For instance, a 2-bit coarse and 5-bit fine structure may be implemented for a compact design, while a 5-bit coarse and 2-bit fine structure may be implemented for increased linearity.

In some cases, the output of circuit 200 may be based on the output of R DAC 205 and the output of R-2 R DAC 210. The output of R DAC 205 may be generated at the output of the MUX of R DAC 205, which, as shown, may connect to scaling resistor 220. The output of R-2 R DAC 210 may be at node 215, or the junction of scaling resistor 220, the depicted DAC output, and the right-most R resistor of R-2 R DAC 210 (e.g., from the perspective of circuit 200).

Accordingly, circuit 200 provides a hybrid R and R-2 R DACs (e.g., R DAC 205 and R-2 R DAC 210). In some examples, one or more R-DACs may be used for coarse bits, providing linearity in the output of the system. One or more R-2 R DACs may be used for fine bits, offering simplified controls and reducing system complexity. The systems and methods described herein maintain the advantages of R and R-2 R DACs, while reducing the disadvantages of R and R-2 R DACs based on coarse-fine segmentation. The hybrid R and R-2 R DACs described herein provide a relatively high linearity performance through R-DAC in coarse bits, and simplifies the decoder and MUX switch design overhead by reducing the number of resistors and decoder logics for the fine bits. Thus, circuit 200 provides a compact design that reduces system cost and increase power efficient with a minimal compromise in linearity.

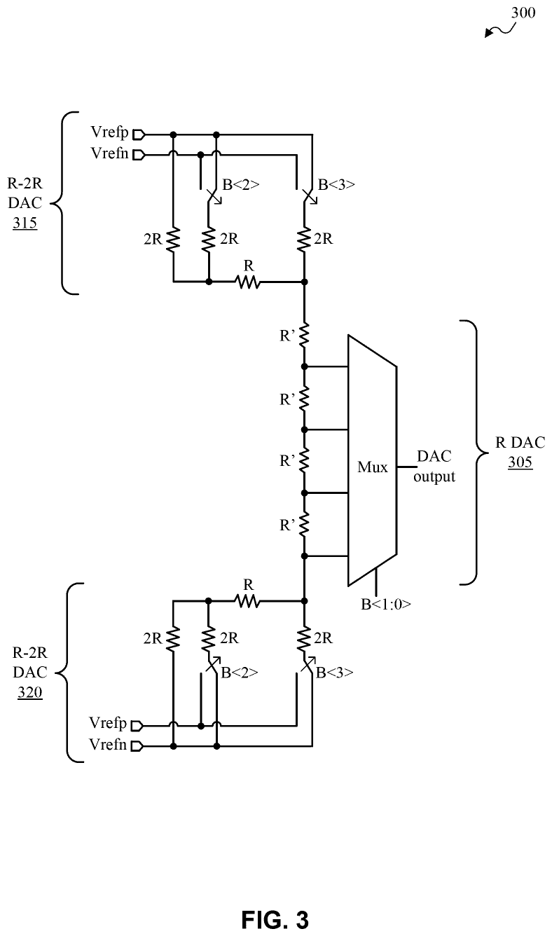

FIG. 3 illustrates an example circuit 300 in accordance with one or more implementations as described herein. In some configurations, one or more aspects of circuit 300 may be implemented by or in conjunction with machine 105, components of machine 105, or any combination thereof.

As shown, circuit 300 includes at least one R DAC (e.g., R DAC 305) and at least one R-2 R DAC. In the illustrated example, circuit 300 may include at least two R-2 R DACs. For example, circuit 300 may include a first DAC (e.g., R-2 R DAC 315) and a second DAC (e.g., R-2 R DAC 320) connected to at least one R DAC (e.g., R DAC 305).

In some cases, the two R-2 R DACs may be configured to convert the coarse bits (e.g., B<2>, B<3>) and R DAC 305 may be configured to convert the fine bits (e.g., B<0>, B<1>) of a control code received by circuit 300.

In the illustrated example, a termination resistor (e.g., left-most 2 R resistor) of R-2 R DAC 315 may be routed to Vrefp, while a termination resistor (e.g., left-most 2 R resistor) of R-2 R DAC 320 may be routed to Vrefn. R-2 R DAC 315 and R-2 R DAC 320 may pass a truncated portion of the coarse voltage range (e.g., 1/4 of the full Vrefp-to-Vrefn range based on 2 coarse bits) to R-DAC 305 for further finer voltage selection.

Circuit 300 provides benefits of reduced area, cost, and settling time. In some cases, the impedance of the R-2 R DACs can interfere with the impedance of R DAC 305 and diminish the linearity. To increase the linearity of the output, the resistor value in the R-DAC may be relatively larger than the resistor values in the R-2 R DACs (e.g., R′>R of R-2 R DAC 315 and R-2 R DAC 320). In some cases, R′ may be greater than 2 R of R-2 R DAC 315 and R-2 R DAC 320.

In some examples, R-2 R DAC 315 may be associated with M coarse bits of the binary code. The M coarse bits may include a most significant bit of the binary code (e.g., include B<2>, B<3>). In some cases, R-2 R DAC 320 may be associated with N fine bits of the binary code. The N fine bits may include a least significant bit of the binary code (e.g., include B<0>, B<1>). In some implementations, M and N may be positive integers (e.g., 0<M<100; 0<N<100). M may be greater than, less than, or equal to N. In various examples, the number of R and 2 R pairs and/or the number of R′ series resistors may vary depending on the number of coarse/fine bits desired.

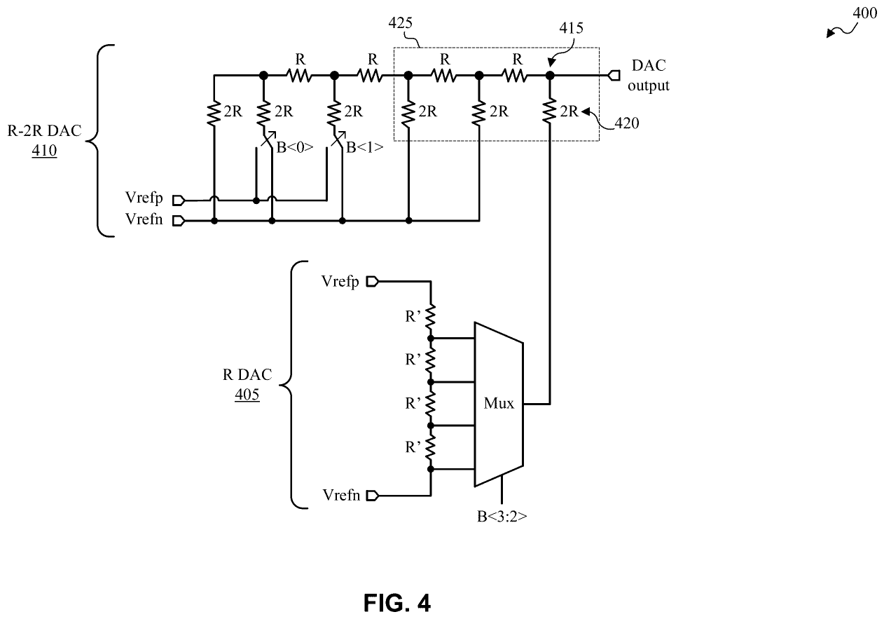

FIG. 4 illustrates an example circuit 400 in accordance with one or more implementations as described herein. In some configurations, one or more aspects of circuit 400 may be implemented by or in conjunction with machine 105, components of machine 105, or any combination thereof.

As shown, circuit 400 may include a first DAC (e.g., R DAC 405) and a second DAC (e.g., R-2 R DAC 410). It is noted that aspects of circuit 400 may be based at least in part on one or more aspects of circuit 200. As shown, circuit 400 may include an R-DAC connected to a mux, where an output of the mux is connected to an R-2 R DAC. The R-DAC of circuit 200 and R-DAC of circuit 400 may connect to a scaling resistor (e.g., scaling resistor 220 and scaling resistor 420, respectively). However, circuit 200 may implement a scaling resistor with a value (e.g., 0.5 R) that differs from the value of resistors of R-2 R DAC 210 (e.g., R and 2 R), while circuit 400 may implement a scaling resistor with a value (e.g., 2 R) that is based on the value of the resistors of R-2 R DAC 410 (e.g., R and 2 R). Additionally, to scale the resolution of R-2 R DAC 410, circuit 400 may add additional R-2 R pairs of resistors in addition to the R-2 R pairs of R-2 R DAC 410.

As shown, R DAC 405 may connect to R-2 R DAC 410 via a scaling resistor (e.g., scaling resistor 420). In some cases, the hybrid R and R-2 R DACs described herein (e.g., circuit 400) may provide a reference voltage for use in controlling one or more aspects of a device (e.g. reference voltage for determining logical 1 or logical 0 in DRAM memory, reference voltage for determining bias voltage for current controls, etc.).

In some cases, R-2 R DAC 410 may be configured to convert the fine bits (e.g., least significant bits) of the control value and R DAC 405 may be configured to convert the coarse bits (e.g., most significant bits). Thus, coarse bits may represent relatively large voltage changes, while fine bits may represent relatively small, precise adjustments. As shown, R-2 R DAC 10 may convert bits B<0> and B<1> of the control value and R DAC 405 may convert bits B<2> and B<3>. Alternatively, R-2 R DAC 410 may be configured to convert the coarse bits of the control value and R DAC 405 may be configured to convert the fine bits. In some examples, the configuration of reference voltages routed to R-2 R DAC 410 (e.g., Vrefp, Vrefn) may be configured based on at least one of output common voltage, desired control range, etc. The output voltage range of R DAC 405, R-2 R DAC 410, and/or of circuit 400 may range from Vrefp to Vrefn.

In some cases, the output of circuit 400 may be based on the output of R DAC 405 and the output of R-2 R DAC 410. The output of R DAC 405 may be generated at the output of the MUX of R DAC 405, which, as shown, may connect to scaling resistor 420. The output of R-2 R DAC 410 may be at node 415, or the junction of scaling resistor 420, the depicted DAC output, and the right-most R resistor of R-2 R DAC 410 (e.g., from the perspective of circuit 400).

As shown, an output of the MUX may connect to scaling resistor 420. Scaling resistor 420 may scale a resolution of R-2 R DAC 410 relative to a resolution of R DAC 405. In some examples, scaling resistor 420 may bridge R DAC 405 to R-2 R DAC 410. The value of scaling resistor 420 may be based on a desired coarse-to-fine ratio, redundancy, impedance mismatch, etc.

In the depicted example, scaling resistor 420 may have a value of 2 R, similar to other 2 R resistors of R-2 R DAC 410. Using same resistor values can lower the costs associated with a given system (e.g., compared to using 0.5 R in circuit 200). In some examples, additional R-2 R pairs may be added between scaling resistor 420 and the R-2 R pairs for B<0> and B<1> of R-2 R DAC 410 (e.g., within area 425). One R-2 R pair may scale a resolution of the fine bits by 2-fold (e.g., 2\hat{ }N, where N is the number of additional R-2 R pairs), providing a 2-fold ratio reduction in the fine bits. In the illustrated example, two additional R-2 R pairs may be added within area 425 for a 4-fold ratio reduction in the fine bits of R-2 R DAC 410. For example, adding two additional R-2 R pairs within area 425 may scale a resolution of the fine bits by a factor of 4 (e.g., 2\hat{ }2=4). Adding three R-2 R pairs within area 425 may scale a resolution of the fine bits by a factor of 8 (e.g., 2\hat{ }3=8), etc. Accordingly, scaling resistor 420 and the additional two R-2 R pairs within area 425 may provide a 4:1 coarse-to-fine ratio for circuit 400, providing a 4-fold ratio reduction in the fine bits. The value of scaling resistor 420 may be selected to match the other 2 R resistors of R-2 R DAC 410. The number of R-2 R pairs added to area 425 may be based on the number of bits converted by R DAC 405 and the desired scaling ratio. For example, the number of R-2 R pairs may be based on the number of bits N converted by R DAC 405. In the depicted example, R DAC 405 may convert 2 bits (e.g., N=2). Accordingly, two R-2 R pairs may be added within area 425. If R DAC 405 is configured to convert 3 bits (e.g., N=3), then three R-2 R pairs may be added within area 425. In various examples, the number of R and 2 R pairs and/or the number of R′ series resistors may vary depending on the number of coarse/fine bits desired. It is noted that, in some examples, the value of a scaling resistor such as scaling resistor 420 may be based on the impact (e.g., non-ideal impact) of one or more switch resistances of R-2 R DAC 410 and/or an effective impedance of R-DAC 405. In some cases, the value of a scaling resistor may vary from a resistor value used in a circuit (e.g., vary from 2 R, vary from R, vary from 0.5 R, etc.) in accordance with the switch resistances of R-2 R DAC 410. Additionally, or alternatively, the value of a scaling resistor may vary from a resistor value used in a circuit based on the effective resistance of R-DAC 405, which may be based on resistors of R-DAC 405 and/or a MUX of R-DAC 405.

In some cases, the depicted MUX can have a finite impedance in series with the equivalent impedance of the resistive ladder of R-2 R DAC 410. Thus, the coarse-to-fine ratio can deviate from a targeted value due to the impedances in the MUX and in the resistive ladder. This can provide the benefit of choosing larger resistance values for R-2 R DAC 410 (e.g., resistors R, 2 R) compared to the resistors of R-DAC 405 (e.g., resistors R′) to increase or maintain linearity in the output of circuit 400.

In some examples, Vrefn (e.g., Vrefn of R-2 R DAC 410) may be configurable to control an output range of circuit 400 (e.g., similar for circuit 200 and/or circuit 300). In some cases, Vrefn may be set to ground. Alternatively, Vrefn may be set to some other minimum voltage level, while Vrefp may set a maximum voltage level. Thus, increasing the voltage level of Vrefn (e.g., above ground) may reduce the range between the minimum and maximum voltage levels of circuit 400. Thus, the value of Vrefn can determine (e.g., increase or decrease) an output range of circuit 400. For example, if Vrefp is 2 volts and the desired range of DAC output is 1 volt, then the voltage applied at Vrefn may be set to some positive voltage above ground (e.g., set to 1 volt for an output voltage range from 1 volt to 2 volts).

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wired and/or wireless communication device such as a switch, router, network interface controller, cellular telephone, smartphone, tablet, netbook, wireless terminal, laptop computer, a femtocell, High Data Rate (HDR) subscriber station, access point, printer, point of sale device, access terminal, or other personal communication system (PCS) device. The device may be wireless, wired, mobile, and/or stationary.

As used within this document, the term “communicate” is intended to include transmitting, or receiving, or both transmitting and receiving. Similarly, the bidirectional exchange of data between two devices (both devices transmit and receive during the exchange) may be described as ‘communicating’, when only the functionality of one of those devices is being claimed. The term “communicating” as used herein with respect to wired and/or wireless communication signals includes transmitting the wired and/or wireless communication signals and/or receiving the wired and/or wireless communication signals. For example, a communication unit, which is capable of communicating wired and/or wireless communication signals, may include a wired/wireless transmitter to transmit communication signals to at least one other communication unit, and/or a wired/wireless communication receiver to receive the communication signal from at least one other communication unit.

Some embodiments may be used in conjunction with various devices and systems, for example, a Personal Computer (PC), a desktop computer, a mobile computer, a laptop computer, a notebook computer, a tablet computer, a server computer, a handheld computer, a handheld device, a Personal Digital Assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless Access Point (AP), a wired or wireless router, a wired or wireless modem, a video device, an audio device, an audio-video (A/V) device, a wired or wireless network, a wireless area network, a Wireless Video Area Network (WVAN), a Local Area Network (LAN), a Wireless LAN (WLAN), a Personal Area Network (PAN), a Wireless PAN (WPAN), and the like.

Some embodiments may be used in conjunction with one way and/or two-way radio communication systems, cellular radio-telephone communication systems, a mobile phone, a cellular telephone, a wireless telephone, a Personal Communication Systems (PCS) device, a PDA device which incorporates a wireless communication device, a mobile or portable Global Positioning System (GPS) device, a device which incorporates a GPS receiver or transceiver or chip, a device which incorporates an RFID element or chip, a Multiple Input Multiple Output (MIMO) transceiver or device, a Single Input Multiple Output (SIMO) transceiver or device, a Multiple Input Single Output (MISO) transceiver or device, a device having one or more internal antennas and/or external antennas, Digital Video Broadcast (DVB) devices or systems, multi-standard radio devices or systems, a wired or wireless handheld device, e.g., a Smartphone, a Wireless Application Protocol (WAP) device, or the like.

Some embodiments may be used in conjunction with one or more types of wireless communication signals and/or systems following one or more wireless communication protocols, for example, Radio Frequency (RF), Infrared (IR), Frequency-Division Multiplexing (FDM), Orthogonal FDM (OFDM), Time-Division Multiplexing (TDM), Time-Division Multiple Access (TDMA), Extended TDMA (E-TDMA), General Packet Radio Service (GPRS), extended GPRS, Code-Division Multiple Access (CDMA), Wideband CDMA (WCDMA), CDMA 2000, single-carrier CDMA, multi-carrier CDMA, Multi-Carrier Modulation (MDM), Discrete Multi-Tone (DMT), Bluetooth™, Global Positioning System (GPS), Wi-Fi, Wi-Max, ZigBee™, Ultra-Wideband (UWB), Global System for Mobile communication (GSM), 2G, 2.5G, 3G, 3.5G, 4G, Fifth Generation (5G) mobile networks, 3GPP, Long Term Evolution (LTE), LTE advanced, Enhanced Data rates for GSM Evolution (EDGE), or the like. Other embodiments may be used in various other devices, systems, and/or networks.

Although an example processing system has been described above, embodiments of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more components of computer program instructions, encoded on computer storage medium for execution by, or to control the operation of, information/data processing apparatus. Alternatively, or in addition, the program instructions can be encoded on an artificially-generated propagated signal, for example, a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (for example multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, for example, an FPGA (field programmable gate array) or an ASIC. The apparatus can also include, in addition to hardware, code that creates an execution environment for the computer program in question, for example code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a component, component, subroutine, object, or other unit suitable for use in a computing environment. A computer program may, but need not, correspond to a file in a file system. A program can be stored in a portion of a file that holds other programs or information/data (for example one or more scripts stored in a markup language document), in a single file dedicated to the program in question, or in multiple coordinated files (for example files that store one or more components, sub-programs, or portions of code). A computer program can be deployed to be executed on one computer or on multiple computers that are located at one site or distributed across multiple sites and interconnected by a communication network. In some cases, a computer program may be executed to fabricate one or more aspects or one or more components of hybrid resistive digital-to-analog converters (DACs) as described herein.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random-access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, for example magnetic, magneto-optical disks, or optical disks. However, a computer need not have such devices. Devices suitable for storing computer program instructions and information/data include all forms of non-volatile memory, media and memory devices, including by way of example semiconductor memory devices, for example EPROM, EEPROM, and flash memory devices; magnetic disks, for example internal hard disks or removable disks; magneto-optical disks; and CD-ROM and DVD-ROM disks. The processor and the memory can be supplemented by, or incorporated in, special purpose logic circuitry.

Embodiments of the subject matter described herein can be implemented in a computing system that includes a back-end component, for example, as an information/data server, or that includes a middleware component, for example, an application server, or that includes a front-end component, for example, a client computer having a graphical user interface or a web browser through which a user can interact with an embodiment of the subject matter described herein, or any combination of one or more such back-end, middleware, or front-end components. The components of the system can be interconnected by any form or medium of digital information/data communication, for example, a communication network. Examples of communication networks include a local area network (“LAN”) and a wide area network (“WAN”), an inter-network (for example the Internet), and peer-to-peer networks (for example ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (for example, an HTML page) to a client device (for example, for purposes of displaying information/data to and receiving user input from a user interacting with the client device). Information/data generated at the client device (for example, a result of the user interaction) can be received from the client device at the server.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples as set forth herein will come to mind to one skilled in the art to which these embodiments pertain, having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A circuit comprising:
a first digital-to-analog converter (DAC) comprising a set of resistors connected in series, the set of resistors connected to a multiplexor, a first resistor of the set of resistors connected to a positive reference voltage of the circuit and a second resistor of the set of resistors connected to a negative reference voltage of the circuit, an output of the circuit providing a reference voltage;
a second DAC comprising a set of R-2 R resistors, the set of R-2 R resistors comprising a first resistor with a value R and a second resistor with a value 2 R, the value R being half the value 2 R; and
a scaling circuit to modify a resolution of the second DAC relative to a resolution of the first DAC, the scaling circuit connecting the first DAC to the second DAC.

2. The circuit of claim 1, wherein the scaling circuit is connected to an output of the multiplexor, an output of the second DAC, and the output of the circuit.

3. The circuit of claim 1, wherein the scaling circuit comprises a scaling resistor, a value of the scaling resistor being based on at least one of (a) an effective impedance of the set of resistors of the first DAC, (b) an effective impedance of the multiplexor of the first DAC, (c) an effective impedance of one or more reference switches of the second DAC, or (d) a quotient determined from the value 2 R and a number of bits associated with the first DAC.

4. The circuit of claim 1, wherein the scaling circuit comprises a scaling resistor with the value 2 R and at least one R-2 R pair of scaling resistors connected to the output of the second DAC.

5. The circuit of claim 1, wherein the set of resistors of the first DAC are of a same type of resistor and of a same value of resistor.

6. The circuit of claim 1, wherein a value of a resistor of the set of resistors of the first DAC is set to the value R from the second DAC.

7. The circuit of claim 1, wherein a value of a resistor of the set of resistors of the first DAC is different from the value R from the second DAC.

8. The circuit of claim 1, wherein:
an input of the circuit comprises a binary code,
the first DAC is associated with M coarse bits of the binary code, the M coarse bits including a most significant bit of the binary code, and
the second DAC is associated with N fine bits of the binary code, the N fine bits including a least significant bit of the binary code, M and N being positive integers, M being greater than, less than, or equal to N.

9. The circuit of claim 1, wherein the second resistor of the set of R-2 R resistors is connected to a reference switch that switches between the positive reference voltage and the negative reference voltage.

10. A circuit comprising:
a first digital-to-analog converter (DAC) comprising a set of resistors connected in series, a first resistor of the set of resistors connected to a multiplexor and a second resistor of the set of resistors connected to the multiplexor;
a second DAC comprising a first set of R-2 R resistors, the first set of R-2 R resistors comprising a first R resistor with a value R and a first 2 R resistor with a value 2 R, the first resistor of the set of resistors being connected to an output of the second DAC;
a third DAC comprising a second set of R-2 R resistors, the second set of R-2 R resistors comprising a second R resistor with the value R and a second 2 R resistor with the value 2 R, the value R being half the value 2 R, the second resistor of the set of resistors being connected to an output of the third DAC;
a termination resistor of the second DAC connected to a positive reference voltage of the circuit; and
a termination resistor of the third DAC connected to a negative reference voltage of the circuit, an output of the circuit providing a reference voltage.

11. The circuit of claim 10, wherein:
the first DAC receives an output of the second DAC and an output of the third DAC, and an output of the multiplexor provides the output of the circuit.

12. The circuit of claim 10, wherein the set of resistors of the first DAC are of a same type of resistor and of a same value of resistor.

13. The circuit of claim 10, wherein a value of a resistor of the set of resistors of the first DAC is set to the value R from the second DAC or the third DAC.

14. The circuit of claim 10, wherein a value of a resistor of the set of resistors of the first DAC is different from the value R from the second DAC or the third DAC.

15. The circuit of claim 10, wherein:
an input of the circuit comprises a binary code,
the first DAC is associated with M coarse bits of the binary code, the M coarse bits including a most significant bit of the binary code, and
the second DAC and the third DAC are associated with N fine bits of the binary code, the N fine bits including a least significant bit of the binary code, M and N being positive integers, M being greater than, less than, or equal to N.

16. The circuit of claim 10, wherein the first 2 R resistor of the second DAC is connected to a reference switch that switches between the positive reference voltage and the negative reference voltage.

17. A device comprising:
a digital-to-analog converter (DAC) circuit configured to output a reference voltage for an operation of the device, the DAC circuit comprising:
a first DAC comprising a set of resistors connected in series, the set of resistors connected to a multiplexor, a first resistor of the set of resistors connected to a positive reference voltage of the circuit and a second resistor of the set of resistors connected to a negative reference voltage of the circuit;
a second DAC comprising a set of R-2 R resistors, the set of R-2 R resistors comprising a first resistor with a value R and a second resistor with a value 2 R, the value R being half the value 2 R; and
a scaling circuit to modify a resolution of the second DAC relative to a resolution of the first DAC, the scaling circuit connecting the first DAC to the second DAC.

18. The device of claim 17, wherein the scaling circuit is connected to an output of the multiplexor, an output of the second DAC, and the output of the circuit.

19. The device of claim 17, wherein the scaling circuit comprises a scaling resistor, a value of the scaling resistor being based on the value 2 R.

20. The device of claim 17, wherein the device comprises a memory device, the device being configured to determine whether a memory cell of the device stores a logical 1 or a logical 0 based on the reference voltage.
